(19) United States
(12) Patent Application Publication
(10) Pub. No.: US 2013/0051966 A1
(43) Pub. Date: Feb. 28, 2013

(54) LOADER FOR SUBSTRATE STORAGE CONTAINER

(71) Applicants: Jong Sam KIM, Suwon-si (KR); Yang-Hyun KIM, Suwon-si (KR); Hyun Jae YI, Suwon-si (KR)

(72) Inventors: Jong Sam KIM, Suwon-si (KR); Yang-Hyun KIM, Suwon-si (KR); Hyun Jae YI, Suwon-si (KR)

(73) Assignee: SAMSUNG ELECTRONICS CO., LTD., Suwon-si (KR)

(21) Appl. No.: 13/590,784

(22) Filed: Aug. 21, 2012

(30) Foreign Application Priority Data
Aug. 24, 2011 (KR) 10-2011-0084665

(51) Int. Cl. H01L 21/677

(52) U.S. Cl. 414/751.1; 414/749.1

(57) ABSTRACT

A loader for a substrate storage container defines a buffer space in which the substrate storage container is temporarily stored between a transfer facility and a semiconductor production facility of a semiconductor production line. The loader includes a load port configured to store the substrate storage container, a buffer port configured to store the substrate storage container, a transfer robot to transfer the substrate storage container within the loader, and a dual entrance sensing device on the transfer robot to determine if the substrate storage container is loaded on the load port and to determine if the substrate storage container is loaded on the buffer port.

### CROSS-REFERENCE TO RELATED APPLICATION

This application claims the benefit of Korean Patent Application No. 2011-0084665, filed on Aug. 24, 2011 in the Korean Intellectual Property Office, the disclosure of which is incorporated in its entirety herein by reference.

### BACKGROUND

1. Field

At least one example embodiment relates to a loader for a substrate storage container, which defines a buffer space in which the substrate storage container is temporarily stored between a transfer facility and a semiconductor production facility of a semiconductor production line.

2. Description of the Related Art

In general, semiconductor manufacturing processes include a photolithography process in which a predesigned circuit pattern is printed on a silicon wafer. The photolithography process includes application, exposure and developing operations.

Semiconductor manufacturing processes are carried out by a variety of equipment to process a wafer using various processing methods. A wafer is fed to a load port of equipment by a transfer facility installed on a production line, such as an Overhead Hoist Transfer (OHT) device, or by a worker while being received in a wafer storage container, such as a Front Opening Unified Pod (FOUP), to prevent the wafer from being contaminated by particles during production. Upon reaching a destination, the wafer is removed from the container and subjected to a desired process.

However, if the OHT device or worker fails to receive the storage container at a required time, or if the device fails to receive the storage container at a proper time due to a limited number of load ports, a wafer is not fed to the production line at a proper time, which causes stoppage of the device or hinders sequential process implementation, resulting in deterioration in the operating ratio of equipment.

### SUMMARY

Therefore, example embodiments provide a space in which a substrate storage container may be temporarily stored between a transfer facility and a semiconductor production facility of a semiconductor production line.

Additional example embodiments will be set forth in part in the description which follows and, in part, will be obvious from the description, or may be learned by practice of the invention.

In accordance with an example embodiment, a loader for a substrate storage container may include a load port on which the substrate storage container may be loaded, a buffer port on which the substrate storage container may be loaded, a transfer robot to transfer the substrate storage container within the loader, and a dual entrance sensing device on the transfer robot to determine whether or not the substrate storage container is loaded on the load port or the buffer port.

The dual entrance sensing device may include a light emitting element to emit light and a light receiving element to sense light, and each of the load port and the buffer port may be provided with a reflector to reflect the light directed from the light emitting element to the light receiving element.

The transfer robot may include a gripper to load the substrate storage container, and the dual entrance sensing device may be on the gripper such that the light emitting element emits light in a downwardly inclined direction into a loading space for the substrate storage container provided on the load port or the buffer port.

The reflector may be obliquely placed on the load port or the buffer port, to reflect incident light from the light emitting element to the light receiving element.

The transfer robot may include a gripper to load the substrate storage container, and the loader may further include a position confirming device to confirm whether or not the gripper may be located in front of a loading space for the substrate storage container provided on the load port or the buffer port.

The position confirming device may include a light emitting element to emit light and a light receiving element to sense light, and each of the load port and the buffer port may be provided with a reflector to reflect the light directed from the light emitting element to the light receiving element if the gripper is located in front of the loading space.

The position confirming device may be on one side of the gripper, and the reflector may be located at one side of the loading space.

The load port may be provided with an entrance sensing device to sense entrance of a transfer device that loads the substrate storage container and a reflector to reflect light emitted from the entrance sensing device so as to return the light to the entrance sensing device.

At least one of the load port and the buffer port may be provided with a seating sensing device to sense whether or not the substrate storage container may be seated on the corresponding port by coming into contact with the corresponding port.

In accordance with an example embodiment, a loader for a substrate storage container may include a frame, a load port on the frame on which the substrate storage container may be loaded, a buffer port on the frame on which the substrate storage container may be loaded, and a transfer robot to transfer the substrate storage container within the loader, wherein the transfer robot may include a sliding fork that may be horizontally movable forward or rearward and vertically movable, the sliding fork being used to load or unload the substrate storage container.

The substrate storage container may be provided at the top thereof with a flange, and the sliding fork may be horizontally movable forward or rearward and be vertically movable with respect to the flange, so as to load or unload the substrate storage container.

The transfer robot may further include a gripper to enable loading and unloading operations of the sliding fork, a vertical carrier to vertically move the gripper, and a horizontal carrier to move the vertical carrier in a width direction of the load port and the buffer port.

The horizontal carrier may be on an upper end of the frame, the vertical carrier may be coupled to the horizontal carrier, and the gripper may be coupled to the vertical carrier.

The buffer port may be provided with a gas feeding device to feed gas into the substrate storage container.

A sliding device may be on a lower end of the frame to guide movement of the frame so as to enable separation of the loader for the substrate storage container from process equipment.

### BRIEF DESCRIPTION OF THE DRAWINGS

These and/or other aspects of the invention will become apparent and more readily appreciated from the following description of the example embodiments, taken in conjunction with the accompanying drawings of which:

FIG. 1 is a perspective view illustrating an example of a loader for a substrate storage container according to an example embodiment;

FIG. 2 is a front view of an example of the substrate storage container according to an example embodiment;

FIG. 3 is an enlarged view illustrating an example of a load port according to an example embodiment;

FIG. 4 is a perspective view illustrating an example of a transfer robot according to an example embodiment;

FIG. 5 is an enlarged view illustrating an example of a gripper according to an example embodiment; and

FIG. 6 is an enlarged view illustrating an example of a buffer port according to an example embodiment.

### DETAILED DESCRIPTION

Reference will now be made in detail to the example embodiments, examples of which are illustrated in the accompanying drawings, wherein like reference numerals refer to like elements throughout.

Hereinafter, a loader for a substrate storage container according to the example embodiments will be described with reference to the drawings.

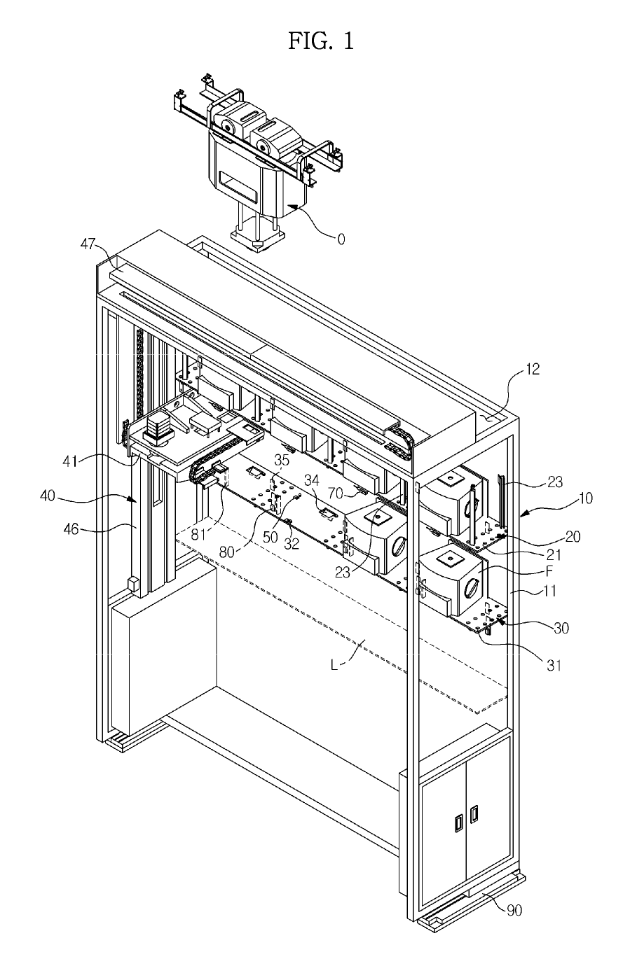

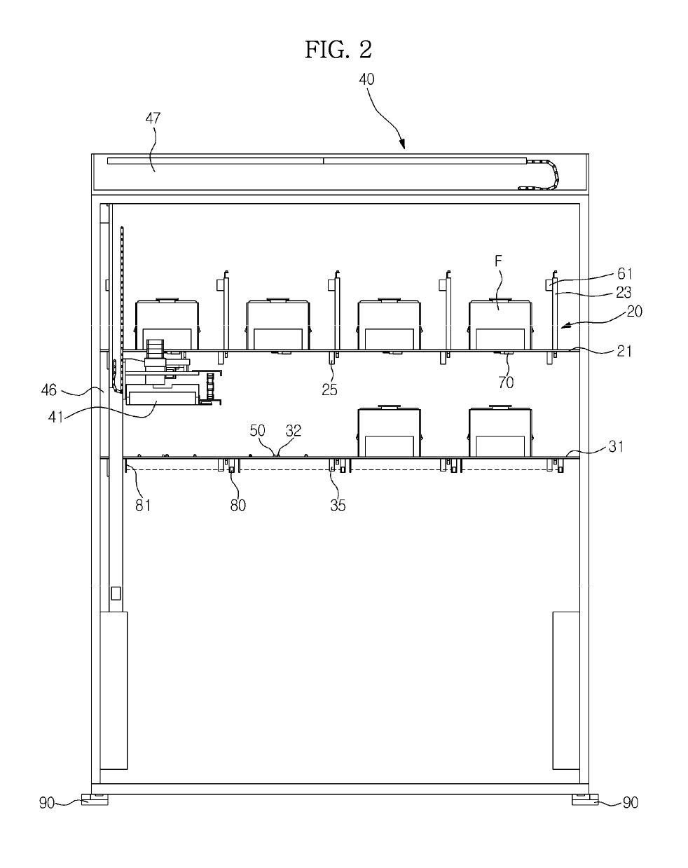

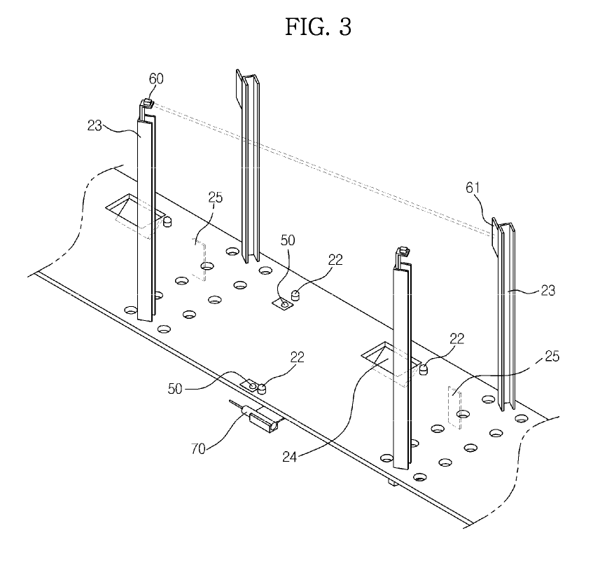

As illustrated in FIGS. 1 to 3, the loader for a substrate storage container may include a main body 10 defining an external appearance of the loader, a load port 20 to which a substrate storage container F may be loaded from the outside, a buffer port 30 to store the substrate storage container F fed to the load port 20, and a transfer robot 40 to transfer the substrate storage container F.

The main body 10 may include a frame 11 having a top opening 12 for entrance of the substrate storage container F to the load port 20 as well as an Overhead Hoist Transfer (OHT) device O used to transfer the substrate storage container F. The load port 20 may be located below the opening 12.

The load port 20 may be configured such that one or more substrate storage containers may be stored. Storing substrate storage containers may involve stacking the substrate storage containers horizontally or vertically. The load port 20 may be configured such that a plurality of substrate storage containers F may be simultaneously stacked. In the illustrated example embodiment, the load port 20 may be configured such that four substrate storage containers F may be simultaneously stacked.

The load port 20 may include a load port shelf 21 defining a loading plane on which the substrate storage container F may be seated. The load port shelf 21 may have a width and length sufficient to provide a space in which the four substrate storage containers F may be simultaneously stacked. The load port shelf 21 may be horizontally mounted to the frame 11 of the main body 10.

Kinematic couplings 22 may be arranged in a triangular shape on the load port shelf 21 at a location where each substrate storage container F may be loaded. The kinematic couplings 22 may serve as positioning means to guide the substrate storage container F transferred by the OHT device O if the substrate storage container F is seated on the load port shelf 21 at an accurate position. Guide recesses (not shown) may be formed in a lower surface of the substrate storage container F at positions corresponding to the kinematic couplings 22.

The kinematic couplings 22 may have a semispherical domed upper end, and the guide recesses may have a plurality of slopes to guide the substrate storage container F to an accurate position of a loading space on the load port shelf 21 with the assistance of the kinematic couplings 22.

A seating sensing device 50 may be provided in the loading space of the load port shelf 21 to confirm whether or not the substrate storage container F may be accurately seated. The seating sensing device 50 may be a contact type sensor which may sense the presence of the substrate storage container F seated in the loading space by coming into contact with the substrate storage container F and may be arranged adjacent to each kinematic coupling 22 to accurately sense the seating of the substrate storage container F. To improve sensing reliability with respect to the seating of the substrate storage container F, a plurality of seating sensing device 50 may be provided on a per loading space basis.

An entrance sensing device 60 may be on the load port 20 to sense if the OHT device O enters the loading space to load the substrate storage container F. The entrance sensing device 60 may be a photo-sensor consisting of a light emitting element and a light receiving element. The entrance sensing device 60 may be attached to an upper end of a support post 23 located at a corner of the loading space.

A reflector 61 may be located at a corner of the loading space diagonally opposite to the entrance sensing device 60, to reflect light emitted from the light emitting element to the light receiving element. Similar to the entrance sensing device 60, the reflector 61 may be attached to an upper end of another support post 23. The reflector 61 may be configured to reflect light irradiated from a position confirming device 45 that will be described hereinafter.

Additionally, a reflector 24 may be provided in each loading space of the load port 20 to reflect light emitted from a light emitting element to a light receiving element of a dual entrance sensing device 44 that will be described hereinafter.

The reflector 24 may be provided on a downwardly inclined slope which may be formed by cutting and bending a portion of the load port shelf 21.

A radio frequency identification (RFID) antenna 70 may be below each loading space of the load port shelf 21, to receive identification information from the substrate storage container F.

The buffer port 30 may have a configuration similar to the load port 20 and may include a buffer port shelf 31. Similar to the load port shelf 21, the buffer port shelf 31 may be provided with the seating sensing devices 50 to confirm whether or not the substrate storage container F may be accurately seated, kinematic couplings 32 to serve as positioning means to accurately guide the substrate storage container F if the substrate storage container F is seated on the buffer port shelf 31 at an accurate position, and reflectors 34 corresponding to the dual entrance sensing device 44.

A slide device 90 may be on opposite lower ends of the main body 10 to ease movement of the main body 10 if separating the loader for the substrate storage container F from process equipment due to, for example, a malfunction of the loader. The slide device 90 may include a linear motion (LM) guide and horizontal moving device and may further include a fixing piece to immobilize the slide device 90.

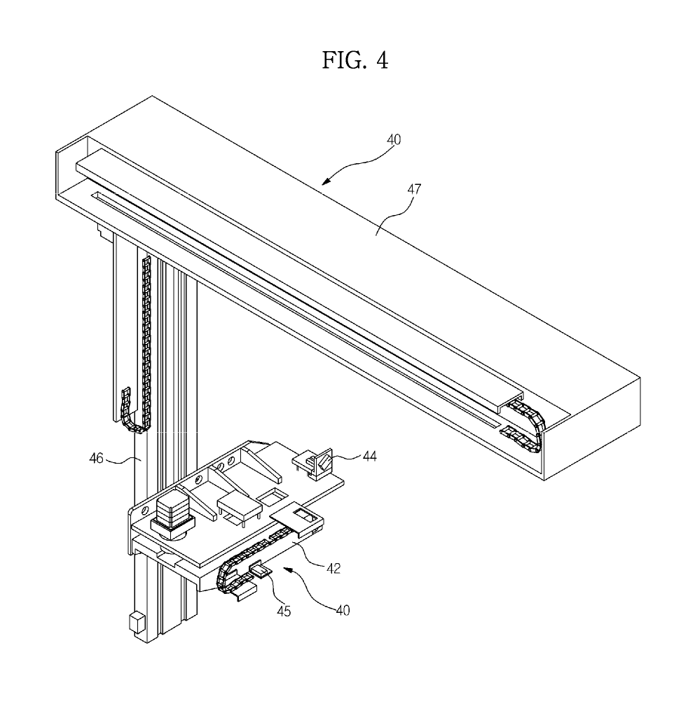

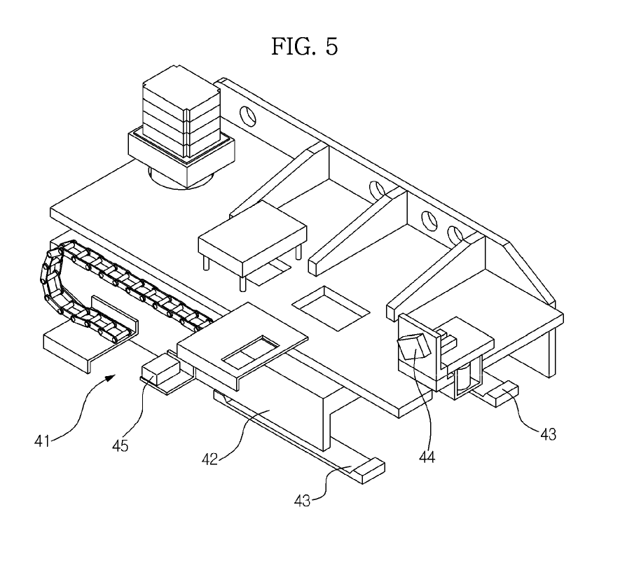

Referring to FIGS. 1, 4 and 5, the transfer robot 40 may be on the main body 10 to transfer the substrate storage container F. The transfer robot 40 may include a horizontal carrier 47, a vertical carrier 46 and a gripper 41, which enable 3-axis transfer of the substrate storage container F.

The horizontal carrier 47 may be a linear motion device, which may be on the top of the frame 11 and may include an LM guide, belt, pulley and drive motor. This is well known in the art and a detailed description thereof is omitted.

The horizontal carrier 47 may be coupled to one end of the vertical carrier 46 so as to move the vertical carrier 46 in a width direction of the load port 20 and the buffer port 30.

Similar to the horizontal carrier 47, the vertical carrier 46 may be a linear motion device including an LM guide, belt, pulley and drive motor. One end of the gripper 41 may be coupled to the vertical carrier 46 so as to vertically move along the vertical carrier 46.

Similar to the horizontal carrier 46, the gripper 41 may be a linear motion device including an LM guide, belt, pulley and drive motor. The gripper 41 may include a sliding fork 43 to load or unload the substrate storage container F. The gripper 41 may move the sliding fork 43 in a direction perpendicular to a transfer direction of the horizontal carrier 47, i.e. in a reciprocating movement direction with respect to the loading space of the load port 20 and the buffer port 30. In conclusion, the substrate storage container F loaded on the sliding fork 43 may be transferred in 3-axes within the main body 10 and may be loaded to or unloaded from the load port 20 and the buffer port 30.

The sliding fork 43 may have a horizontal surface extending lengthwise in a direction parallel to the transfer direction of the gripper 41. A pair of sliding forks 43 may be spaced apart from each other by a distance corresponding to a width of a flange F-1 of the substrate storage container F. A loading operation by the sliding fork 43 may have several steps. First, if the gripper 41 horizontally moves the sliding fork 43 forward if the sliding fork 43 is located close to the flange F-1 of the substrate storage container F, the sliding fork 43 enters below the flange F-1 of the substrate storage container F. Then, if the vertical carrier 46 moves the gripper 41 upward by a vertical spacing between the sliding fork 43 and the flange F-1, the flange F-1 may be seated on the sliding fork 43 and the substrate storage container F is loaded. Thereafter, if the gripper 41 retracts the siding fork 43, the loading operation is completed. An unloading operation may be performed in the reverse order of the loading operation if the substrate storage container F is loaded on the sliding fork 43.

The gripper 41 may be provided with the above-described dual entrance sensing device 44 at a position above the sliding fork 43. The dual entrance sensing device 43 may be a photo-sensor including a light emitting element to emit light and a light receiving element to sense light. The light emitting element of the dual entrance sensing device 43 may be downwardly inclined to emit light in a diagonal direction of the loading space such that the light emitted from the light emitting element may be reflected by the reflectors 24 and 34 provided at the load port 20 and the buffer port 30 to allow the light receiving element to sense the reflected light if the substrate storage container F is not loaded in the loading space. The reflectors 24 and 34 may be arranged to create a reflection environment to reflect light from the light emitting element to the light receiving element.

The dual entrance sensing device 44 may allow a controller (not shown) to confirm whether or not the substrate storage container F is loaded in the loading space prior to loading the substrate storage container F. This may prevent dual entrance of the substrate storage container F. However, by confirming whether or not the substrate storage container F is loaded in the loading space if attempting to discharge the substrate storage container F from the loading space, a malfunction, such as attempted discharge from an empty space, may be prevented.

The above-described position confirming device 45 may be on the gripper 41. The position confirming device 45 may serve as a sensing device that confirms whether or not the gripper 41 is accurately located in front of the loading space defined on the load port 20 and the buffer port 30 for loading or unloading of the substrate storage container F. With the position confirming device 45, malfunction upon loading or unloading of the substrate storage container F by the gripper 41 may be prevented.

The position confirming device 45 may be a photo-sensor including a light emitting element to emit light and a light receiving element to sense light. Reflectors 25 and 35 may be arranged in each loading space to reflect light from the light emitting element to the light receiving element of the position confirming device 45. The reflectors 25 and 35 may be secured to lower surfaces of the load port shelf 21 and the buffer port shelf 31 so as to be arranged at one side of each loading space. In the case of the load port 20, the reflector 61 corresponding to the above-described entrance sensing device 60 may be used.

A load port L of process equipment (not shown) connected to the loader for the substrate storage container F according to an example embodiment may be located below the buffer port 30. A substrate storage container confirming device 80 and a reflector 81 may be arranged on a per loading space basis of the load port L and secured to the lower surface of the buffer port shelf 31, to confirm whether or not the substrate storage container F is loaded on the load port L.

The substrate storage container confirming device 80 may be a photo-sensor including a light emitting element to emit light and a light receiving element to sense light. The substrate storage container confirming device 80 and the reflector 81 may be arranged at opposite sides of each loading space, such that the reflector 81 reflects light from the light emitting element to the light receiving element of the substrate storage container confirming device 80.

The reflector 35, which may be secured to the lower surface of the buffer port shelf 31 to correspond to the position confirming device 45, may also serve to confirm the position of the gripper 41 even if the substrate storage container F is transferred to the load port L by the transfer robot 40.

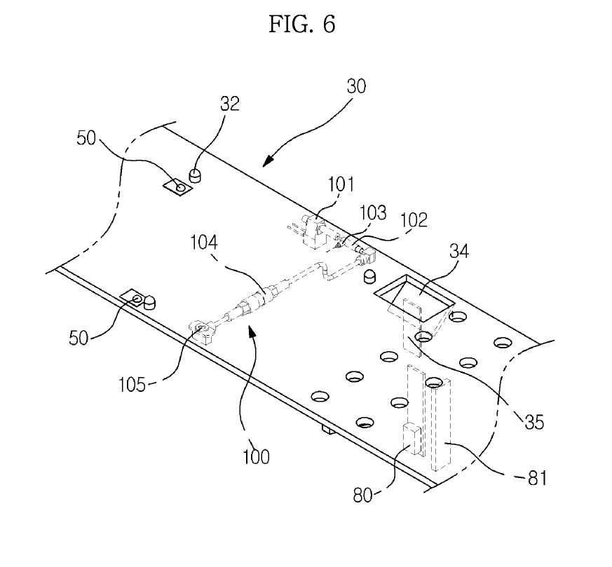

As illustrated in FIG. 6, a gas feeding device 100 may be provided below the buffer port shelf 31 to substitute the interior air of the substrate storage container F with Clean Dry Air (CDA) that does not contain compound and dust having a negative effect on a substrate within the substrate storage container F loaded on the buffer port 30, or nitrogen (N2) by purging.

The gas feeding device 100 may include an adjustable valve 101 to adjust gas feed, an orifice 102 to create a flow path for gas feed, a pressure sensor 103 on the orifice 102, a filter 104 to remove particles from the fed gas, and a nozzle 105 to eject the gas having passed through the filter 104 into the substrate storage container F.

To allow the gas ejected from the nozzle 105 to enter the substrate storage container F if the substrate storage container F is loaded on the load port 20, a gas feed hole (not shown) may be perforated in the bottom of the substrate storage container F.

Although example embodiments have been shown and described, it would be appreciated by those skilled in the art that changes may be made in these example embodiments without departing from the principles and spirit of the invention, the scope of which is defined in the claims and their equivalents.

What is claimed is:

1. A loader for a substrate storage container, comprising:
a load port, configured to store the substrate storage container;
a buffer port, configured to store the substrate storage container;
a transfer robot configured to transfer the substrate storage container within the loader; and
a dual entrance sensing device on the transfer robot configured to determine if the substrate storage container is loaded on the load port and configured to determine if the substrate storage container is loaded on the buffer port.

2. The loader according to claim 1, wherein the dual entrance sensing device includes a light emitting element to emit light and a light receiving element to sense light, the load port includes a load port reflector configured to reflect the light directed from the light emitting element to the light receiving element and the buffer port includes a buffer port reflector configured to reflect the light directed from the light emitting element to the light receiving element.

3. The loader according to claim 2, wherein the transfer robot includes a gripper to load the substrate storage container, and
wherein the dual entrance sensing device is on the gripper such that the light emitting element is configured to emit light in a downwardly inclined direction into at least one of a load port loading space and a buffer port loading space.

4. The loader according to claim 3, wherein the load port reflector is obliquely placed on the load port and configured to reflect incident light from the light emitting element to the light receiving element and the buffer port reflector is obliquely placed on the buffer port and configured to reflect incident light from the light emitting element to the light receiving element.

5. The loader according to claim 1, wherein the transfer robot includes a gripper to load the substrate storage container, and
wherein the loader further comprises a position confirming device configured to determine if the gripper is located in front of a load port loading space and configured to determine if the gripper is located in front of a buffer port loading space.

6. The loader according to claim 5, wherein the position confirming device includes a light emitting element configured to emit light and a light receiving element configured to sense light, the load port includes a load port reflector configured to reflect the light directed from the light emitting element to the light receiving element if the gripper is located in front of the load port loading space and the buffer port includes a buffer port reflector configured to reflect the light directed from the light emitting element to the light receiving element if the gripper is located in front of the buffer port loading space.

7. The loader according to claim 6, wherein the position confirming device is on one side of the gripper, the load port reflector is located on one side of the load port loading space and the buffer port reflector is located on one side of the buffer port loading space.

8. The loader according to claim 1, wherein the load port includes an entrance sensing device configured to determine an entrance of a transfer device that loads the substrate storage container and an entrance sensing reflector configured to reflect light emitted from the entrance sensing device back to the entrance sensing device.

9. The loader according to claim 1, wherein at least one of the load port and the buffer port includes a seating sensing device configured to determine if the substrate storage container is seated on the corresponding port by coming into contact with the corresponding port.

10. A loader for a substrate storage container, comprising:
a frame;
a load port on the frame, the load port configured to store the substrate storage container;
a buffer port on the frame, the buffer port configured to store the substrate storage container; and
a transfer robot configured to transfer the substrate storage container within the loader,
wherein the transfer robot includes a sliding fork that is horizontally movable forward or rearward and vertically movable, the sliding fork configured to load or unload the substrate storage container.

11. The loader according to claim 10, wherein a flange is attached at the top of the substrate storage container and the sliding fork is horizontally movable forward or rearward and vertically movable with respect to the flange, so as to load or unload the substrate storage container.

12. The loader according to claim 10, wherein the transfer robot further includes a gripper configured to enable loading and unloading operations of the sliding fork, a vertical carrier configured to vertically move the gripper, and a horizontal carrier configured to move the vertical carrier in a width direction of the load port and the buffer port.

13. The loader according to claim 12, wherein the horizontal carrier is on an upper end of the frame, the vertical carrier is coupled to the horizontal carrier, and the gripper is coupled to the vertical carrier.

14. The loader according to claim 10, wherein the buffer port includes a gas feeding device to feed gas into the substrate storage container.

15. The loader according to claim 10, wherein a sliding device is on a lower end of the frame to guide movement of the frame so as to enable separation of the loader for the substrate storage container from process equipment.
